(19) United States
(12) Patent Application Publication
(10) Pub. No.: US 2024/0353482 A1
(43) Pub. Date: Oct. 24, 2024

(54) METHOD OF OPTIMIZING CABLING OF AT LEAST ONE DEVICE UNDER TEST AND SYSTEM FOR PERFORMING TESTS ON AT LEAST ONE DEVICE UNDER TEST

(71) Applicant: Rohde & Schwarz GmbH & Co. KG, Muenchen (DE)

(72) Inventors: Sebastian ENGEL, Muenchen (DE); Kristin SCHWARZMUELLER, Muenchen (DE); Victor ARROYO, Muenchen (DE); Andrew SCHAEFER, Muenchen (DE); Detlef WIESE, Muenchen (DE); RuhUllah SHAH, Muenchen (DE)

(73) Assignee: Rohde & Schwarz GmbH & Co. KG, Muenchen (DE)

(21) Appl. No.: 18/303,328

(22) Filed: Apr. 19, 2023

(51) Int. Cl. G01R 31/28

(52) U.S. Cl. CPC G01R 31/2889; G01R 31/2834

(57) ABSTRACT

The present disclosure relates to a method of optimizing cabling of at least one device under test when performing tests on the at least one device under test. At least one device under test with a plurality of connectors is provided. The connectors are capable of supporting different frequencies and/or different signal directions. At least one testing device with a plurality of test ports is provided. The test ports are capable of supporting different frequencies and/or different signal directions. The at least one device under test and the testing device are to be connected with each other via a cabling. The cabling between the at least one device under test and the at least one testing device is optimized by a processing circuit. Further, a system is disclosed.

### FIELD OF THE DISCLOSURE

Embodiments of the present disclosure relate to a method of optimizing cabling of at least one device under test when performing tests on the at least one device under test. Further, embodiments of the present disclosure relate to a system for performing tests on at least one device under test.

### BACKGROUND

In the state of the art, it is known to test a device under test according to a test campaign, namely several tests. Depending on the tests planned, several (test) programs have to be executed, for instance on multiples testing devices used for testing the device under test. Generally, the test programs may be executed on one testing device or several testing devices.

Some programs are allowed to be executed in parallel with other programs, possibly sharing the same testing device. However, some programs are blocking other programs until they are finished. Moreover, some of the programs have to be executed only once, whereas other programs have to be executed several times. In addition, some of the testing devices can only be used by a single program simultaneously.

Accordingly, constraints have to be taken into account when performing the tests of the device under test, which are based on different circumstances as indicated above.

Generally, the program can only be executed when the assigned testing device is prepared for execution of the respective program. A respective program is ready for execution when the assigned testing device is connected properly with the device under test, e.g. by cables, over-the-air interfaces, or similar.

Such connection of the testing device has possibly further specific constraints to be fulfilled. Those constraints can be related to other programs using the same testing devices and thus define when multiple programs can or cannot be executed in parallel.

So far, the scheduling of the tests planned is done manually, which requires a lot of efforts and time, especially due to the fact that modern test campaigns become more complex due to the number of testing devices involved as well as the number of test programs to be executed. Due to the complex task, the entire test campaign may last longer than necessary since some of the tests planned cannot be executed as scheduled. This results in higher costs that shall be avoided.

In addition, test plans comprising several tests planned may relate to testing several different devices under test, e.g. in parallel or subsequently, resulting in a even more complex scheduling.

Accordingly, there is a need for improving the efficiency of performing a test campaign having several tests.

### SUMMARY

Embodiments of the present disclosure provide a method of optimizing cabling of at least one device under test when performing tests on the at least one device under test. In an embodiment, the method comprises the steps of: providing at least one device under test with a plurality of connectors, wherein the connectors are capable of supporting different frequency and/or different signal directions, providing at least one testing device with a plurality of test ports, wherein the test ports are capable of supporting different frequency and/or different signal directions, wherein the at least one device under test and the testing device are to be connected with each other via a cabling, and optimizing the cabling between the at least one device under test and the at least one testing device by a processing circuit.

Further, embodiments of the present disclosure provide a system for performing tests on at least one device under test. In an embodiment, the system comprises at least one device under test with a plurality of connectors. The connectors are capable of supporting different frequency and/or different signal directions. The system further comprises at least one testing device with a plurality of test ports. The test ports are capable of supporting different frequency and/or different signal directions. The at least one device under test and the testing device are to be connected with each other via a cabling. The system comprises a processing circuit that is capable of optimizing the cabling between the at least one device under test and the at least one testing device.

The main idea of the present disclosure relates to providing assistance to an operator of the system regarding connection of the device under test with the testing device, for example when and how to change the cabling. Accordingly, the embodiments of the method and the system allow for a fast and optimal execution of the tests, thereby improving the overall efficiency. Hence, it is no longer necessary that the cabling, e.g. the specification of the connection set up for scheduled devices, has to be done by experts through manually added policies, which is expensive and complex. In some embodiments, a higher degree of automation is obtained, as more automation steps are obtained.

For instance, embodiments of the system are capable of outputting information about the optimized cabling, for instance via an output interface. Then, the operator of the system can follow the information output.

Alternatively, the system itself is capable of adapting the cabling, e.g. without any manual interaction. The processing circuit may control a component of the system accordingly.

An aspect provides that the processing circuit is based on, for example, quantum annealing or an application-specific integrated circuit. The processing circuit may comprise hardware like a quadratic solver as digital annealer, an application-specific integrated circuit (ASIC) chip or a quantum annealer, for example.

Another aspect provides that the processing circuit executes, for example, an algorithm which, when executed on the processing circuit, optimizes the cabling between the at least one device under test and the testing device. In other words, the processing circuit may be capable of executing an algorithm which, when executed on the processing circuit, is capable of optimizing the cabling between the at least one device under test and the testing device. The algorithm may relate to an optimization algorithm, for example. The optimization algorithm may optimize the cabling based on inputs, for instance information about the tests to be performed, the at least one device under test and/or the at least one testing device. Thus, the processing circuit may be, for example, an optimization engine.

In some embodiments, the algorithm is an artificial intelligence algorithm. Therefore, the optimization of the routing is done in a computer-aided manner. For instance, the artificial intelligence algorithm is a machine learning algorithm that learns to operate on its own. The artificial intelligence algorithm may use reinforcement learning, supervised learning and/or reward function with optimization.

According to a further aspect, a switch unit is provided, for example, that is connected with the at least one device under test and the at least one testing device. The cabling between the at least one device under test and the at least one testing device may be established via the switch unit. The switch unit has several ports to which the device under test and the testing device can be connected. Moreover, the switch unit may have several signal lines via which signals can be exchanged between the device under test and the testing device.

In some embodiment, the processing circuit may be configured to control the switch unit in order to adapt the setting of the switch unit, thereby adapting the cabling. In some embodiments, the processing circuit controls the switch unit based on the optimized cabling determined.

For instance, the switch unit comprises at least one combiner, a signal switching and conditioning unit, a switch, an amplifier, a splitter and/or an attenuator. Accordingly, different ports may be combined to one signal line by the combiner or one signal line is split by the splitter such that two ports are connected to the same signal line. In addition, the signals forwarded via the switch unit may be processed, e.g. conditioned, amplified, attenuated. The switch may be a relay in some embodiments.

In some embodiments, the processing circuit considers the switch unit when optimizing the cabling between the at least one device under test and the at least one testing device. In other words, the processing circuit may be capable of considering, for example, the arrangement of the switch unit when optimizing the cabling between the at least one device under test and the at least one testing device. The processing circuit may obtain information about the switch unit, for example its arrangement, as input data that is taken into account when determining the optimized cabling. The information about the switch unit, e.g. the number of ports, its internal routing and similar, may be used to automatically determine the optimized cabling. In some embodiments, constraints provided by the switch unit are taken into consideration.

A further aspect provides that the processing circuit considers, for example, the at least one device under test, the at least one testing device as well as a test plan comprising planned tests when optimizing the cabling between the at least one device under test and the at least one testing device. In other words, the processing circuit may be capable of considering the switch unit when optimizing the cabling between the at least one device under test and the at least one testing device. In some embodiments, the number of devices under test and the number of testing devices as well as their individual characteristics are also taken into account when determining the optimized cabling. Since the at least one device under test and the at least one testing device also have certain constraints, for instance with regard to their types of connectors/ports.

According to another aspect, the processing circuit returns, for example, a scheduling plan with an optimized order of the planned tests. The system may comprise an output interface connected with the processing circuit, and wherein the processing circuit may be configured to return a scheduling plan via the output interface, which comprises an optimized order of the planned tests. In general, the system is enabled to determine the scheduling plan, for example based on the same inputs used for determining the optimized cabling. The scheduling plan, namely the order to the tests planned, may be output on a display or a screen for informing the operator of the system. However, the scheduling plan may also be used by a post processing device that receives the scheduling plan.

A further aspect provides that the processing circuit returns, for example, a cabling plan that provides the optimized cabling. The system may comprise an output interface connected with the processing circuit, and wherein the processing circuit may be configured to return a cabling plan via the output interface, which provides the optimized cabling. The cabling plan relates to a temporal order of the cabling, for example when a (re-) cabling is necessary due to the tests planned.

### BRIEF DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a system according to an embodiment of the present disclosure;

FIG. 2 shows an overview illustrating a cabling plan output by an output interface according to an embodiment of the present disclosure; and

FIG. 3 shows an overview of a method according to an embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

Similarly, any steps described herein may be interchangeable with other steps, or combinations of steps, in order to achieve the same or substantially similar result. Moreover, some of the method steps can be carried serially or in parallel, or in any order unless specifically expressed or understood in the context of other method steps.

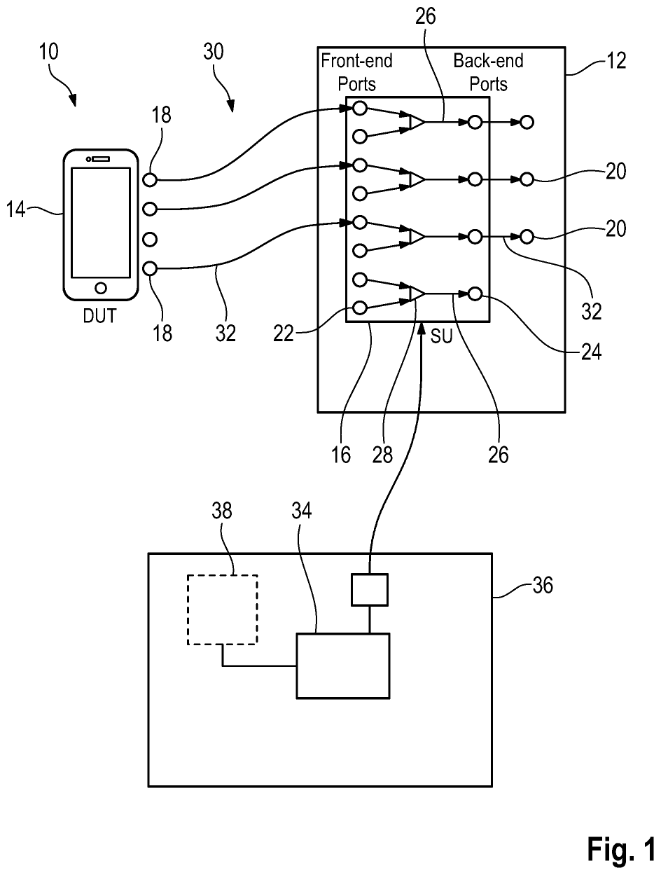

FIG. 1 illustrates a system 10 that relates to a test system, also called a test and measurement system. In the embodiment shown, the system 10 comprises at least one testing device 12 and at least one device under test 14. Generally, the system 10 may comprise several testing devices 12 and/or several devices under test 14.

In the embodiment of FIG. 1, the test device 12 and the device under test 14 are connected with each other via a switch unit 16 that is interposed between the testing device 12 and the device under test 14.

The device under test 14 has a plurality of connectors 18 that are capable of supporting different frequencies and/or different signal directions. Thus, the connectors 18 may relate to transmission connectors or reception connectors. Further, different frequency bands may be associated with the respective connectors 18. For instance, these connectors 18 are antenna connectors.

The testing device 12 has a plurality of test ports 20 that are also capable of supporting different frequencies and/or different signal directions. Thus, the test ports 20 may relate to transmission ports or reception ports. Further, different frequency bands may be associated with the respective test ports 20.

As mentioned above, the test device 12 and the device under test 14 are connected with each other via a switch unit 16. Specifically, the connectors 18 are connected with the test ports 20 via the switch unit 16. The switch unit 16 has front end ports 22 as well as back end ports 24. As shown in FIG. 1, the connectors 18 are at least partly connected with the front end ports 22 of the switch unit 16, whereas the back end ports 24 of the switch unit 16 are connected with the test ports 20 of the testing device 12.

In addition, the switch unit 16 may comprise at least one signal line 26. In some embodiments, each of the front end ports 22 and the back end ports 24 is connected to a respective signal line 26. Moreover, the switch unit may have one or more internal components 28 located in a respective signal line 26. The internal component 28 may be a combiner (as shown in FIG. 1), a switching and conditioning unit, a switch, an amplifier, a splitter and/or an attenuator. The switch may be a relay.

Therefore, signals processed by the internal signal lines 26 of the switch unit 16 may be combined, split, conditioned, amplified and/or attenuated. This depends on the setting of the switch unit 16.

Accordingly, the device under test 14 and the testing device 12 are connected with each other via a cabling 30 that is inter alia established by connecting cables 32. The connecting cables 32 may be connected with the device under test 14 and the switch unit 16, for example the connectors 18 and the front end ports 22. Alternatively or additionally, the cables 32 may also be provided between the testing device 12 and the switch unit 16, for example the test ports 20 and the back end ports 24. Hence, the switch unit 16 is also part of the cabling 30 in the shown embodiment.

As indicated above, the system 10 may generally comprise several devices under test 14 and/or several testing devices 12 for different testing purposes. Therefore, the cabling 30 may be altered during a test plan comprising several tests, solely due to the different devices under test 14 and/or the different testing devices 12 used for testing. However, the cabling 30 may be altered also during the test plan due to the different tests planned in general.

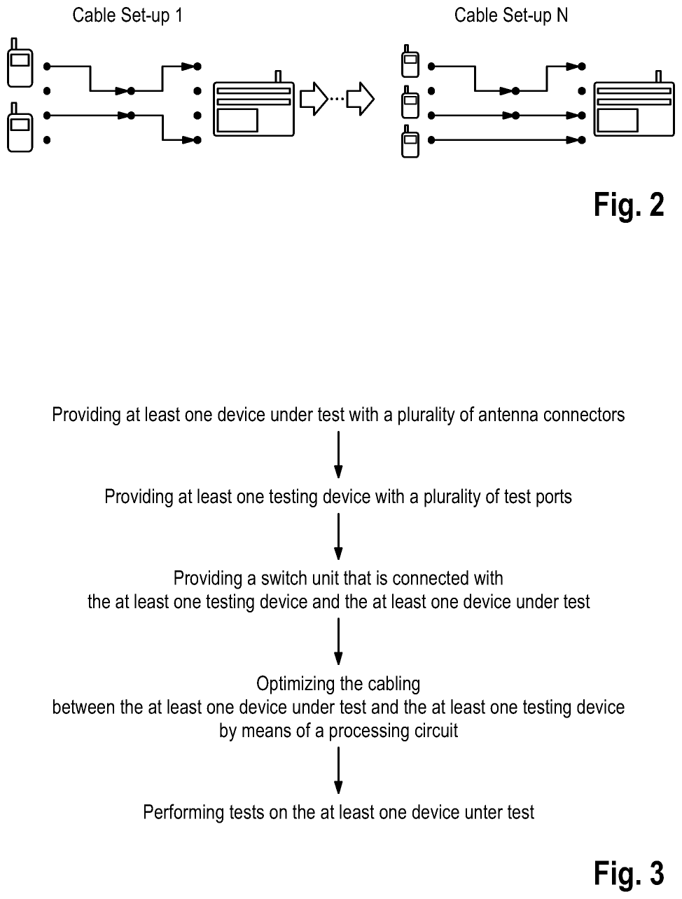

The different cablings 30 used by the system 10 are schematically shown in the embodiment of FIG. 2. In some embodiments, different cable set-ups are illustrated that are used for performing different tests.

Depending on the number of tests, number of devices under test 14 and/or the number of testing devices 12 as well as their characteristics, different constraints have to be considered when setting up the respective cabling 30.

For optimizing the entire testing, it is necessary to find an optimized cabling plan as well as an optimized scheduling plan according to which the different tests planned are performed in an optimized order.

Accordingly, the system 10 has a processing circuit 34 that may be integrated within a computing device 36, for instance a server unit or a computational device. Hence, the processing circuit 34 may be located locally or remotely. In a certain embodiment, the processing circuit 34 may be integrated within the testing device 12.

In general, the processing circuit 34 is capable (e.g., programmed) for optimizing the cabling 32 between the at least one device under test 14 and the at least one testing device 12, for example via the switch unit 16. Toward that end, the processing circuit 34 considers the at least one device under test 14, for example all devices under test 14, the at least one testing device 12, for example all testing devices 14, as well as a test plan comprising the planned tests. Optionally, the processing circuit 34 may also take the switch unit 16 into account.

Based on this information, namely the devices under test 14 to be tested, the available testing devices 12, the types of tests to be performed and optionally information about the switch unit 16, the processing circuit 34 is (e.g., programmed) to determine the optimized cabling 30. In some embodiments, a cabling plan is determined that provides the optimized cabling 30 over the testing time.

The system 10 may have an output interface 38, e.g. the computing device 36 having the processing circuit 34. The output interface 38 is connected with the processing circuit 34 such that the cabling plan (shown in FIG. 2) can be output via the output interface 38 in order to inform an operator of the system 10 accordingly.

Besides the cabling plan, the processing circuit 34 is also enabled (e.g., programmed) to determine a scheduling plan according to which the planned tests are ordered in an optimized manner, thereby reducing the time required for re-cabling as well as the respective efforts related thereto. The scheduling plan may be output via the output interface 38 in order to inform the operator of the system 10.

Generally, the processing circuit 34 may be based on or include quantum annealing or an application-specific integrated circuit (ASIC). In some embodiments, an optimization problem is solved by the processing circuit 34 when considering the different input parameters, e.g. the types and number of devices under tests 14, the types and number of testing devices 12 available as well as the tests planed and optionally the information about the switch unit 16, e.g. the number of ports 22, 24, the internal routing of the signal lines 26 as well as the internal components 28.

Further, the processing circuit 34 executes an algorithm (e.g., program code, script, application, etc.) which, when executed on the processing circuit 34, optimizes the cabling 30 between the at least one device under test 14 and the testing device 12. The algorithm determines based on the input parameters mentioned above, the cabling plan such that the test planned can be performed in the most efficient manner.

For instance, the operator is informed how to connect the device under test 14 and the testing device 12 (via the switch unit 16) efficiently while reducing the cabling efforts simultaneously.

The respective algorithm may be an artificial intelligence (AI) algorithm that processes the input parameters in order to output the optimized cabling, namely the cabling plan and/or the scheduling plan. For instance, the artificial intelligence algorithm uses reinforcement learning, supervised learning and/or reward function with optimization. Thus, a machine learning algorithm may be used.

The system 10 shown in FIG. 1 is generally enabled to perform the method illustrated in FIG. 3 according to which the at least one device under test 14 with a plurality of (antenna) connectors 18 is provided. Additionally, the at least one testing device 12 with the plurality of test ports 20 is provided. In addition, the switch unit 16 is provided that is connected with the at least one testing device 12 and the at least one device under test.

The processing circuit 34 considers the respective components provided by the system 10, namely the device under test 14, the at least one testing device 12 as well as the switch unit 16. The processing circuit 34 also considers the test planned according to the test plan that might be input by the operator of the system 10.

Hence, the processing circuit 34 takes all this input parameters, namely the information input, into account when optimizing the cabling 30 between the at least one device under test 14 and the at least one testing device 12 such that an optimized cabling plan and an optimized scheduling plan is obtained by the processing circuit 14.

According to an example embodiment, the optimized cabling plan and the optimized scheduling plan are output via the output interface 38. Hence, the operator of the system 10 may (re-) cable the device under test 14 and the testing device 12 accordingly. Moreover, the operator of the system 10 may initiate the tests planned based on the scheduling plan.

However, the processing circuit 34 may also control the switch unit 16 and/or the at least one testing device 12 such that no manual interaction is required. In some embodiments, the processing circuit 34 sends control signals to the switch unit 16 to adapt the internal signal routing, thereby affecting a (re-) cabling in order to obtain the optimized cabling during the tests performed. Simultaneously, the processing circuit 34 may control the at least one testing device 12 to perform the tests planned in the optimized order at the respective times.

In any case, e.g. the semi-automatic or full-automatic system 10, the planned tests are performed on the at least one device under test 14, wherein re-cabling efforts are reduced anyway due to the optimized cabling plan and/or the scheduling plan determined automatically.

Therefore, efforts associated with performing the test plan having several tests planned, namely a test scenario, can be reduced, thereby increasing the overall efficiency.

In general, the tests planned may be performed by executing (test) programs, each having multiple tasks to be executed on different testing devices 14.

According to a certain example, a conformance testing of devices under tests 12 is described hereinafter with reference to FIG. 1. The devices under test 14 may be mobile devices, e.g. tablets or mobile phones.

The at least one device under test 14 is wired to the testing device 12 in order to ensure the correct signal transmission. The device under test 14 has the multiple (antenna) connectors 18 where cables 32 are connected. Every (antenna) connector 18 is capable of transmitting and/or receiving signals. The testing device 12 has test ports 20 that are capable of verifying signals.

The switch unit 16 has the front end ports 22 to which the device under test 14 is connected by its (antenna) connectors 18. The switch unit 16 also has the back end ports 24 to which the testing device 12 is connected via its test ports 20.

When the device under test 14 sends a signal, the signal passes through the switch unit 16 to be forwarded to the test ports 20 of the testing device 12, which verify the signal. When the device under test 14 receives a signal, the signal comes from the testing device 12 and is routed through the switch unit 16 to the device under test 14.

Within the switch unit 16, there are several signal lines 26 from the front end ports 22 where the device under test 14 is connected to the back end ports 24 where the testing device 12 is connected. During a test run, the cables 32 have to be re-routed and re-connected several times. To keep the test effort as low as possible, it is advantageous to perform as many tests as possible simultaneously or with the same cabling 30 (cable setup).

As described above, the processing circuit 34 provides the optimized cabling 30, e.g. the cabling plan and the scheduling plan, in order to keep the test efforts as low as possible.

For instance, the circuitry of the switch unit 16, namely the internal signal lines 26 and the internal components 28, can be abstracted to a graph. One approach is to automate the finding of paths for the signal flow by a graph search algorithm executed on the processing circuit 34. In order to be able to make an ideal cabling plan, all signal lines 26 and the internal components 28 of the switch unit 16 must be explored.

In some embodiments, the processing circuit 34 receives a specified set of programs to be executed, namely the test plan with the tests planned, and a specified set of testing devices 12 and/or connection elements being available. The optimization engine, namely the processing circuit 34, generates an optimal scheduling plan and cabling plan for program executions, based on an underlying objective set by the operator of the system 10.

As described above, the scheduling plan contains the plan which testing devices 12 and cabling 30 should be used for which program in the execution list, namely which test planned, as well as when which program should be executed, namely at which point of time the test shall be started. This is illustrated in FIG. 2.

Generally, the system 10 may have multiple options of using different optimization engines, namely processing circuits 34, which can be considered as local processing circuits 34 or external remotely reachable processing circuits 34, e.g. server units, used by the system 10.

In a certain implementation, the operators load a planned list of tests planned, namely a test plan, available testing devices 12 and underlying connection elements, e.g. cables 32 and switch unit 16, into the testing device 12, e.g. a conformance testing device, or the separately formed computing device 36. The respective device receiving the information may have the processing circuit 34. However, it is not necessary since the testing device 12 may be enabled to forward the information received to the separately formed computing device 36 having the processing circuit 34. Hence, computational power may be outsourced, for example in case of using a server unit.

The respective device, e.g. the testing device 12 or the computing device 36, is starting the system 10. As indicated above, the respective device uses a local or remotely reachable optimization engine, namely the processing circuit 34, to determine a scheduling plan and a cabling plan. The respective planes may be returned to the operator, for instance via the output interface 38.

Then, the operator can start the suggested tests planned according to the scheduling plan and follow the returned cabling plan and the assigned testing devices 12. Alternatively, an automatization tool generates the underlying cabling set up according to the cabling plan per executed time step. This can be done easily when controlling the switch unit 16 by the processing circuit 34.

If the loaded list of execution programs (planned tests), available testing devices 12, and connection elements (switch unit 16 and cables 32) allow for enough variation, the underlying objective for the optimization engine can be adjusted by the operator for preferring scheduling and/or cabling plans that cause the tests to be finished earlier, e.g. in shorter execution steps. For instance, parallel program executions are allowed.

Further, the operator can also adjust the objective for obtaining scheduling and/or cabling plans with cable set ups as similar as possible in two subsequent steps. This allows for low efforts when setting up a new cable setup from one execution step to another.

Generally, the cabling plan and the scheduling plan together comprise time points at which the cabling 30 has to be altered and how it has to be altered.

Various embodiments of the present disclosure or the functionality thereof may be implemented in various ways, including as non-transitory computer program products. A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably). Such non-transitory computer-readable storage media include all computer-readable media (including volatile and non-volatile media).

Embodiments of the present disclosure may also take the form of an apparatus, system, computing device, computing entity, and/or the like executing instructions stored on computer-readable storage media to perform certain steps or operations. The computer-readable media include cooperating or interconnected computer-readable media, which exist exclusively on a processing or processor system or distributed among multiple interconnected processing or processor systems that may be local to, or remote from, the processing or processor system. However, embodiments of the present disclosure may also take the form of an entirely hardware embodiment performing certain steps or operations.

Various embodiments are described above with reference to block diagrams and/or flowchart illustrations of apparatuses, methods, systems, and/or computer program instructions or program products. It should be understood that each block of any of the block diagrams and/or flowchart illustrations, respectively, or portions thereof, may be implemented in part by computer program instructions, e.g., as logical steps or operations executing on one or more computing devices. These computer program instructions may be loaded onto one or more computer or computing devices, such as special purpose computer(s) or computing device(s) or other programmable data processing apparatus (cs) to produce a specifically-configured machine, such that the instructions which execute on one or more computer or computing devices or other programmable data processing apparatus implement the functions specified in the flowchart block or blocks and/or carry out the methods described herein.

These computer program instructions may also be stored in one or more computer-readable memory or portions thereof, such as the computer-readable storage media described above, that can direct one or more computers or computing devices or other programmable data processing apparatus(es) to function in a particular manner, such that the instructions stored in the computer-readable memory produce an article of manufacture including computer-readable instructions for implementing the functionality specified in the flowchart block or blocks.

The computer program instructions may also be loaded onto one or more computers or computing devices or other programmable data processing apparatus(es) to cause a series of operational steps to be performed on the one or more computers or computing devices or other programmable data processing apparatus(es) to produce a computer-implemented process such that the instructions that execute on the one or more computers or computing devices or other programmable data processing apparatus(es) provide operations for implementing the functions specified in the flowchart block or blocks and/or carry out the methods described herein.

It will be appreciated that the term computer or computing device can include, for example, any computing device or processing structure. While embodiments of the present disclosure utilize an application-specific integrated circuit (ASIC), other computing or processing structures may be employed, including but not limited to a processor (e.g., a microprocessor), a central processing unit (CPU), a digital signal processor (DSP), a field-programmable gate array (FPGA), a graphics processing unit (GPU), a system on a chip (SoC), or the like, or any combinations thereof.

Accordingly, blocks of the block diagrams and/or flowchart illustrations support various combinations for performing the specified functions, combinations of operations for performing the specified functions and program instructions for performing the specified functions. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

In some embodiments, the processing circuit 34 is programmed to carry out one or more steps of any of the methods disclosed herein. In some embodiments, one or more computer-readable media associated with or accessible by the processing circuit 34 contains computer readable instructions embodied thereon that, when executed by the processing circuit 34, cause the processing circuit 34 to perform one or more steps of any of the methods disclosed herein.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately.” “near.” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure. Further, it will be appreciated that embodiments of the present disclosure may employ any combination of features described herein.

Throughout this specification, terms of art may be used. These terms are to take on their ordinary meaning in the art from which they come, unless specifically defined herein or the context of their use would clearly suggest otherwise.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A method of optimizing cabling of at least one device under test when performing tests on the at least one device under test, wherein the method comprises the steps of:
providing at least one device under test with a plurality of connectors, wherein the connectors are capable of supporting different frequencies and/or different signal directions,
providing at least one testing device with a plurality of test ports, wherein the test ports are capable of supporting different frequencies and/or different signal directions, wherein the at least one device under test and the testing device are to be connected with each other via a cabling, and
optimizing the cabling between the at least one device under test and the at least one testing device by a processing circuit.

2. The method according to claim 1, wherein the processing circuit is based on quantum annealing or an application-specific integrated circuit.

3. The method according to claim 1, wherein the processing circuit executes an algorithm which, when executed on the processing circuit, optimizes the cabling between the at least one device under test and the testing device.

4. The method according to claim 3, wherein the algorithm is an artificial intelligence algorithm.

5. The method according to claim 4, wherein the artificial intelligence algorithm uses reinforcement learning, supervised learning and/or reward function with optimization.

6. The method according to claim 1, wherein a switch unit is provided that is connected with the at least one device under test and the at least one testing device.

7. The method according to claim 6, wherein the processing circuit considers the switch unit when optimizing the cabling between the at least one device under test and the at least one testing device.

8. The method according to claim 1, wherein the processing circuit considers the at least one device under test, the at least one testing device as well as a test plan comprising planned tests when optimizing the cabling between the at least one device under test and the at least one testing device.

9. The method according to claim 8, wherein the processing circuit returns a scheduling plan with an optimized order of the planned tests.

10. The method according to claim 1, wherein the processing circuit returns a cabling plan that provides the optimized cabling.

11. A system for performing tests on at least one device under test, wherein the system comprises at least one device under test with a plurality of connectors, wherein the connectors are capable of supporting different frequencies and/or different signal directions, wherein the system further comprises at least one testing device with a plurality of test ports, wherein the test ports are capable of supporting different frequencies and/or different signal directions, wherein the at least one device under test and the testing device are to be connected with each other via a cabling, and wherein the system comprises a processing circuit that is capable of optimizing the cabling between the at least one device under test and the at least one testing device.

12. The system according to claim 11, wherein the processing circuit is based on quantum annealing or an application-specific integrated circuit.

13. The system according to claim 11, wherein the processing circuit is capable of executing an algorithm which, when executed on the processing circuit, is capable of optimizing the cabling between the at least one device under test and the testing device.

14. The system according to claim 13, wherein the algorithm is an artificial intelligence algorithm.

15. The system according to claim 11, wherein a switch unit is provided that is connected with the at least one device under test and the at least one testing device.

16. The system according to claim 15, wherein the switch unit comprises at least one combiner, a signal switching and conditioning unit, an amplifier, a splitter, a switch and/or an attenuator.

17. The system according to claim 15, wherein the processing circuit is capable of considering the switch unit when optimizing the cabling between the at least one device under test and the at least one testing device.

18. The system according to claim 11, wherein the processing circuit is capable of considering the at least one device under test, the at least one testing device as well as a test plan comprising planned tests when optimizing the cabling between the at least one device under test and the at least one testing device.

19. The system according to claim 18, wherein the system comprises an output interface connected with the processing circuit, and wherein the processing circuit is configured to return a scheduling plan via the output interface, which comprises an optimized order of the planned tests.

20. The system according to claim 11, wherein the system comprises an output interface connected with the processing circuit, and wherein the processing circuit is configured to return a cabling plan via the output interface, which provides the optimized cabling.
